(19) United States
(12) Patent Application Publication
(10) Pub. No.: US 2026/0115754 A1
(43) Pub. Date: Apr. 30, 2026

(54) APPARATUS AND PROCESS FOR APPLYING A COATING COMPOSITION TO A SUBSTRATE BY SPRAYING

(71) Applicant: Akzo Nobel Coatings International B.V., Amsterdam (NL)

(72) Inventors: Niclas Nils Erik Andersson, Klågerup (SE); Claes Gunnar Stefan Sjödahl, Färjestaden (SE); Patrik Birger Otto Henriksson, Malmö (SE); Nils Gustav Martin Olsson Karlberg, Dalby (SE); Jonas Gert Persson, Amsterdam (NL)

(21) Appl. No.: 19/474,464

(22) PCT Filed: Apr. 18, 2024
(86) PCT No.: PCT/EP2024/060590

§ 371 Date: Oct. 10, 2025

(30) Foreign Application Priority Data
Apr. 18, 2023 (EP) 23168502.5

(51) Int. Cl. B05B 15/555; C23C 16/448

(52) U.S. Cl. CPC B05B 15/555; C23C 16/4486

(57) ABSTRACT

Apparatus for depositing a coating composition onto a substrate, said apparatus comprising: • a) a spray applicator (1) comprising a coating composition reservoir, a pump, a spray nozzle (2) and a coating composition conduit configured to connect the coating composition reservoir to the spray nozzle; • b) a vapor emitter; and • c) electromechanical means for automatically moving the spray nozzle relative to the substrate; characterized in that the vapor emitter is configured to emit vapor directly onto the spray nozzle, 2024/218233 and which vapor emitter comprises: • i) a fluid reservoir capable of holding the fluid to be vaporized; • ii) a vaporizer configured to convert the fluid to a vapor; and • iii) a vapor conduit (6) configured to deliver a stream of vapor from the vaporizer through a vapor conduit aperture directly onto the spray nozzle (2). A process for depositing a coating composition on a substrate; and a coated substrate.

### CROSS REFERENCE TO RELATED APPLICATION

This application is a 35 U.S.C. § 371 national phase application of PCT Application No. PCT/EP2024/060590 (published as WO/2024/218233), filed Apr. 18, 2024, which claims the benefit of priority to EP Application No. 23168502.5, filed Apr. 18, 2023, each of which is incorporated herein by reference in their entirety.

### TECHNICAL FIELD

The present disclosure relates to apparatus for use in a system of spray coating a substrate. In particular, it relates to an apparatus and process for preventing the clogging of a spray nozzle during use.

### BACKGROUND

Apparatus for spraying substrates, for example furniture, automotive or construction components, with a coating composition in an industrial environment are well-established. Spray coating may be done by hand but in a large volume process is typically automated to some degree. In a continuous process a number of substrates sequentially have a coating composition applied them by spraying from a single apparatus, for example on a production line. In such a process, in order to minimize waste, spraying of coating composition is typically paused between spraying each substrate or part thereof.

Spraying apparatus may use air at a range of different pressures to apply a coating composition. In an industrial setting this is typically classed as either high pressure or low pressure spraying. A problem which arises in particular with low pressure spraying apparatus is that of the coating composition to be sprayed coalescing or drying at the tip of the nozzle and causing a (partial) blockage of the nozzle aperture. This is more likely to occur with longer intervals between spraying periods. Further it is more likely to occur with coating compositions having a high solids content, for example a high pigment load. A partial blockage can cause an uneven spray which leads to uneven coverage of the substrate in coating composition and subsequent inadequate coating of the substrate.

U.S. Pat. No. 5,344,073A describes a method of cleaning overspray build up from a spray nozzle of a coating gun used to apply coating to the inside of cans. A liquid cleaning solution of solvent or water is sprayed from a cleaning spray nozzle onto the spray nozzle of the coating gun at periods when the coating gun is not spraying.

US2009226598 AA describes a method of applying a functional coating for example a coating for the transport and release of a therapeutic agent, a radio opaque coating or biocompatible coating is applied to a medical device, for example a stent. Solvent vapor may be applied proximal to the nozzle to avoid clogging by evaporative drying of the coating. This allows use of more volatile solvents such as toluene and tetrahydrofuran in high precision printing, whereas low volatile solvents, for example xylene and dimethylformamide, are otherwise required. Solvent is applied as a liquid by filling or capiliary action; vapor is generated by evaporation from the vapor emitter.

JP2003071374 A2 describes a method for preventing nozzle clogging of a coating machine which emits an aqueous emulsion composition. Humidity is maintained at the nozzle by applying a cap to the nozzle when not in use.

There remains a need for an apparatus for applying a coating composition, which apparatus has a reduced incidence of spray nozzle clogging when used in stop-start spray applications. Further, there is a need for avoiding nozzle clogging after a pause in spraying for 30 seconds or more, in particular in repeated start-stop operations. Still further there is a need for avoiding nozzle clogging in low pressure spraying apparatus and/or with coating compositions having a high solids content and/or low boiling point solvent, and for spraying in a hot or humid environment.

### SUMMARY

The objects of the disclosure are met by the first embodiment of the disclosure, which provides an apparatus for depositing a coating composition onto a substrate, said apparatus comprising:
a) a spray applicator comprising a coating composition reservoir, a pump, a spray nozzle and a coating composition conduit configured to connect the coating composition reservoir to the spray nozzle;
b) a vapor emitter; and
c) electromechanical means for automatically moving the spray nozzle relative to the substrate;
characterized in that the vapor emitter is configured to emit vapor directly onto the spray nozzle, and which vapor emitter comprises:
i) a fluid reservoir capable of holding the fluid to be vaporized;
ii) a vaporizer configured to convert the fluid to a vapor; and
iii) a vapor conduit configured to deliver a stream of vapor from the vaporizer through a vapor conduit aperture directly onto the spray nozzle.

In a second embodiment, the present disclosure provides A process for depositing a coating composition on a substrate, said process comprising simultaneously;
a) providing a coating composition to a spray nozzle and spraying the coating composition from the spray nozzle onto the substrate;
b) emitting a stream of vapor from an aperture of a vapor emitter; and
c) moving automatically by electromechanical means the spray nozzle relative to the substrate;
characterized in that the stream of vapor is emitted from an aperture of the vapor emitter directly onto the spray nozzle.

### BRIEF DESCRIPTION OF THE DRAWINGS

FIG. 1 depicts a spray nozzle emitting a spray of coating composition according to the state of the art.

FIG. 2 depicts a spray nozzle which is partially blocked and emits an uneven spray of coating composition according to the state of the art.

FIG. 3 depicts a spray nozzle with a vapor conduit configured to deliver vapor through a vapor conduit aperture directly onto the exterior of the spray nozzle.

FIG. 4 depicts a spray nozzle with a vapor conduit delivering vapor through a vapor conduit aperture directly onto the exterior of the spray nozzle.

FIG. 5 depicts a spray nozzle emitting a spray of coating composition and a vapor conduit delivering vapor through a vapor conduit aperture directly onto the exterior of the spray nozzle.

FIG. 6 Depicts two substrates to which a coating composition has been evenly applied through a clean spray nozzle.

FIG. 7 depicts a substrate to which an uneven coating composition has been applied through a partially clogged spray nozzle.

### DETAILED DESCRIPTION

The apparatus comprises c) electromechanical means for automatically moving the spray nozzle relative to the substrate. The substrate may move or the spray nozzle may move or both the substrate and spray nozzle may move. One embodiment involves a continuous process for spraying multiple substrates which are carried by conveyor system past one or more spray nozzles which are in a fixed position. This embodiment is particularly suitable for the spray coating of a panel, for example a solid wood or engineered wood panel. Both or either of the edges and the faces of the panel can be coated with such an apparatus. An alternative embodiment comprises a similar system for conveying the multiple substrates but in addition to the substrates being carried on a conveyor, the spray nozzle moves. For example, the spray nozzle might scan across the surface of a panel in a direction perpendicular to the direction of travel. The spray nozzle might also rotate allowing it to apply coating composition evenly to more complicated shapes of substrates, for example molded or shaped panels. A further alternative is that the spray nozzle may be moved and/or rotated to apply coating composition in to a complicated 3-dimensional shape, which may be on a conveyor system or may be fixed in place. For example, spray coating of a vehicle body or component or a piece of furniture.

Movement of the spray-nozzle relative to the substrate is automated. In an industrial setting this may be programmed to follow a defined pattern. In a more advanced embodiment, the movement may comprise a detection system which provides feedback to the apparatus allowing adjustment of the relative movement in order to improve the quantity or evenness of coating composition applied. Electromechanical means refers to a device powered by electricity and providing mechanical movement.

The vapor emitter comprises:
i) a fluid reservoir capable of holding the fluid to be vaporized;
ii) a vaporizer configured to convert the fluid to a vapor; and
iii) a vapor conduit configured to deliver a stream of vapor from the vaporizer through a vapor conduit aperture directly onto the spray nozzle.

The fluid reservoir is typically a tank capable of holding the fluid to be vaporized. Typically the tank has a capacity of from 1 to 50 litres, for example 5 to 20 litres. The reservoir may be filled continuously, for example by connection to a continuous fluid supply, wherein flow rate may be measured and controlled. Alternatively, the reservoir may be filled by batch wise addition of fluid.

The vaporizer converts the fluid to a vapor. Optionally, the vaporizer converts the fluid to a vapor directly in the fluid reservoir. The vaporizer may comprise any suitable means of generating a vapor from a liquid. For example, it may comprise one or more of a fan, a heat source or ultrasonic inducer. In various embodiments, the vaporizer comprises an ultrasonic transducer. On application of electric current, the ultrasonic transducer vibrates at ultrasonic frequency which acts to convert the fluid from a liquid to a gas. The vaporizer may be part of a humidifier. The vaporizer and fluid reservoir together may be part of a humidifier. Use of an ultrasonic inducer has the advantage of being efficient and producing vapor at ambient temperature, which reduces safety considerations compared with heating the fluid.

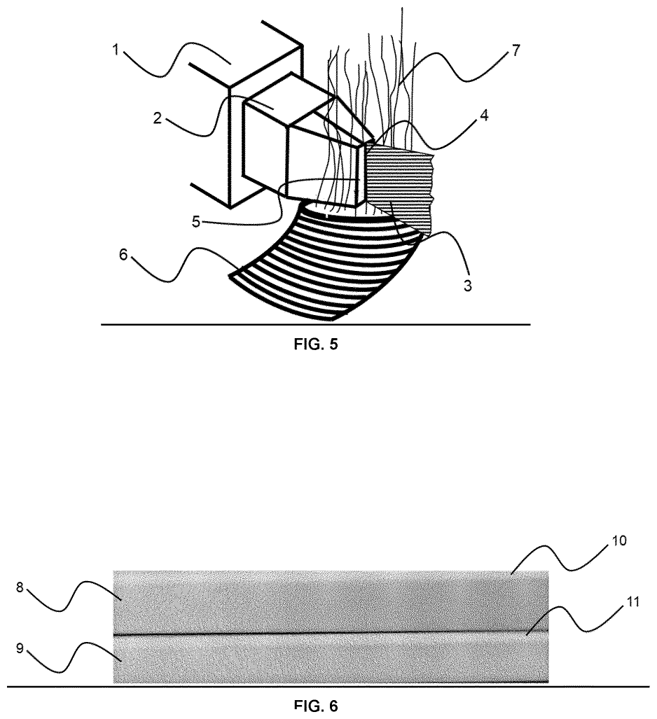

The vapor conduit may for example be a hose which at one end is connected to the vaporizer and which at the other end is proximal to the spray nozzle. Direction of emission and flow rate of emission of vapor may be adapted for the application. In various embodiments, as illustrated in FIGS. 4 and 5, the vapor conduit emits vapor below the spray nozzle and vapor flow perpendicular the direction of spraying. Alternative embodiments include emission of vapor parallel to or at an angle to the direction of spray. In various embodiments, the end of the vapor conduit which is configured to deliver vapor to the spray nozzle may be connected to or even integrated into the spray nozzle itself. In such an embodiment the coating composition is delivered to the spray nozzle from an interior aperture and the vapor is emitted to the spray nozzle from one or more exterior apertures, wherein both interior and exterior apertures are in the spray nozzle. The diameter of the conduit may vary considerably. However it is typically from 40 mm to 200 mm, for example from 80 to 150 mm.

The vapor may be conveyed through the vapor conduit simply by the expansion of the fluid vaporizing. Alternatively, a fan or pump may be connected to the vapor conduit in order to convey the vapor. The vapor may be heated in the vapor conduit. The presence of vapor at the spray nozzle reduces or prevents the coalescence of coating composition in or on the spray nozzle. Vapor may be emitted during a pause in spraying, or both during spraying and during a pause in spraying. In various embodiments, vapor is emitted during both spraying and a pause in spraying.

The vapor conduit aperture is the same as the vapor emitter aperture. This is the aperture from which vapor is emitted. The vapor conduit may be a tube or hose. The vapor conduit aperture may be the end of the vapor conduit, or it may be a valve, a nozzle, a jet or a constriction at the end of the vapor conduit.

In various embodiments, the vapor conduit aperture is located within 100 mm of the spray nozzle. Typically, the vapor conduit aperture is located within 80 mm of the spray nozzle; preferably within 60 mm, 40 mm, 20 mm or 10 mm of the spray nozzle. In a further embodiment, the vapor conduit aperture is integrated within the spray nozzle.

In various embodiments, the spray nozzle can also be heated or cooled. This may be done by connecting a temperature control unit to the spray nozzle, by for example fluid filed heat transfer tubes. Typically the spray nozzle is cooled. The temperature of the spray nozzle may typically be from 0° C. to 20° C., for example from 1 to 15° C. or from 4° C. to 10° C. Cooling the spray nozzle has the advantage of increasing the humidity at the spray nozzle, or even condensing solvent, for example water, on the spray nozzle. By doing this the system is more stable with respect to preventing drying of the coating composition in the nozzle.

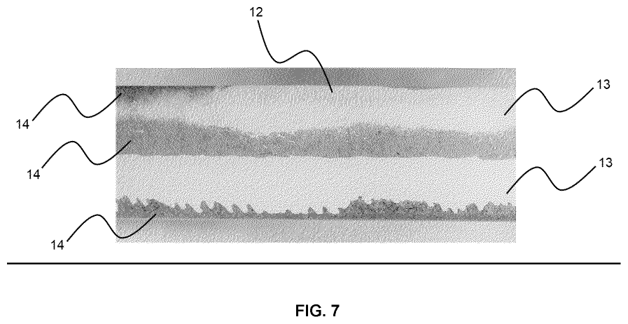

In various embodiments, the spray nozzle is suitable for applying coating composition simultaneously to at least two surfaces of the substrate. The spray nozzle may have a circular aperture, an oval aperture or an elongated or slit aperture. Partial clogging of an aperture is more evident in the spray pattern of an elongated or slit aperture, as can be seen with reference to FIG. 7. In the case of a circular or oval nozzle, the aperture may have a dimension of from 0,005 to 4 mm. In the case of a slit aperture or elongated aperture, the aperture may have a shortest dimension of from 0,005 to 4 mm. In the case of a slit aperture or elongated aperture, the aperture may have a longest dimension of from 1 to 50 mm.

The spray apparatus may comprise more than one spray nozzle. For example for spraying a large area of complex shape, multiple spray nozzles may be employed. Typically, the apparatus may comprise up to 6 nozzles, for example 1, 2, 3, 4 or 5 spray nozzles. The vapor emitter may be configured to emit vapor to more than one nozzle. In various embodiments, the vapor emitter comprises a single fluid reservoir, a single vaporizer and multiple vapor conduits to emit vapor to multiple spray-nozzles. Alternatively, the spray apparatus may comprise more than one vapor emitter.

In various embodiments, the coating composition is sprayed intermittently onto the substrate and the vapor is emitted continuously to the spray nozzle. In various embodiments the coating composition is sprayed intermittently onto one or more substrates and the vapor is emitted continuously directly onto the spray nozzle. In such embodiments, the application of coating composition to the substrate(s) is in a start-stop operation. The time period of spraying depends on the nature of the substrate. The time period for a pause in spraying may typically be at least 5 seconds, 10 seconds, for example 15 seconds, 20 seconds or 30 seconds. The time period for a pause in spraying may be, for example in case of an unexpected stop in the apparatus be several hours; normally however the time period for a pause in spraying is less than 30 minutes, for example less than 20 minutes, less than 10 minutes or less than 5 minutes.

The coating composition may be provided to the spray nozzle at any suitable pressure. The problem of nozzle clogging is more prevalent at lower pressure spray apparatus. Accordingly, the coating composition may be provided to the nozzle at a pressure of from 0.005 to 3 MPa. In various embodiments, the coating composition is provided to the spray nozzle at a pressure of from 0.1 to 2 MPa.

The vapor may be applied at room temperature. This is advantageous because no energy is required in heating or cooling the fluid or vapor. Alternatively, the temperature of either the fluid or the vapor may be adjusted so that vapor is applied at the desired temperature. Any suitable temperature may be used depending on the substrate, the vapor and the environmental conditions. Typically the temperature is at least 3° C., for example at least 5° C., at least 8° C. or at least 10° C. Typically the temperature is at most 70° C., for example at most 60° C. or 50° C. or at most 40° C. In various embodiments, the vapor provided to the spray nozzle is at a temperature of from 10° C. to 40° C.

Any suitable fluid may be used in the vaporizer. In various embodiments the vapor is water vapor. Water is particularly suitable because it has few health and safety requirements for handling and is readily available.

The vapor may be identical to, or different from, a solvent present in the coating composition. In various embodiments, the vapor is identical to a solvent present in the coating composition. In various embodiments, the coating composition is a water-based coating composition. Accordingly the vapor is water vapor and the coating composition is water-based. The coating composition may be applied as a single layer or in multiple layers. The coating composition may be applied as one layer of a multiple layer coating.

When the stream of vapor is water, the humidity at the aperture of the vapor conduit is spray nozzle is typically at least 85%. Preferably it is at least 90%, at least 95% or even at least 98%. Because the vapor stream is directed onto the spray nozzle, the humidity at the spray nozzle is also typically at least 85%. Preferably it is at least 90%, at least 95% or even at least 98%. The vapor stream is typically a fine mist. Droplet sizes may be less than 100 μm, less than 50 μm or even less than 30 μm in diameter.

Vapor may be generated from a fluid by known techniques. For example, the fluid can be evaporated, with or without heating, to provide a vapor. Alternatively, the fluid can In various embodiments, the vapor is generated from a fluid by an ultrasonic transducer in contact with the fluid. A suitable vaporizer is a humidifier.

The spray nozzle automatically moves relative to the substrate. In various embodiments, the spray nozzle automatically moves in a plane perpendicular to the relative direction of movement of the substrate to the spray nozzle. The spray nozzle may be controlled by a computer system. The computer system may be programmed for a specific substrate and coating process.

The substrate may be any material and any shape. Suitable materials depend on the nature of the coating composition to be applied. Typical substrates include metals, polymers, glass, composites, concrete and wood-based products. In various embodiments, the substrate is solid wood or engineered wood. Examples of engineered wood are plywood, oriented strand board (OSB), medium density fibreboard (MDF) and particle board.

In various embodiments, the process is a continuous process of coating multiple substrates. Such a process may be part of a spray coating line or even part of a larger production line.

In various embodiments, the apparatus as defined in any one of claims 1 to 4 is employed in the process.

### Detailed Description of Figures

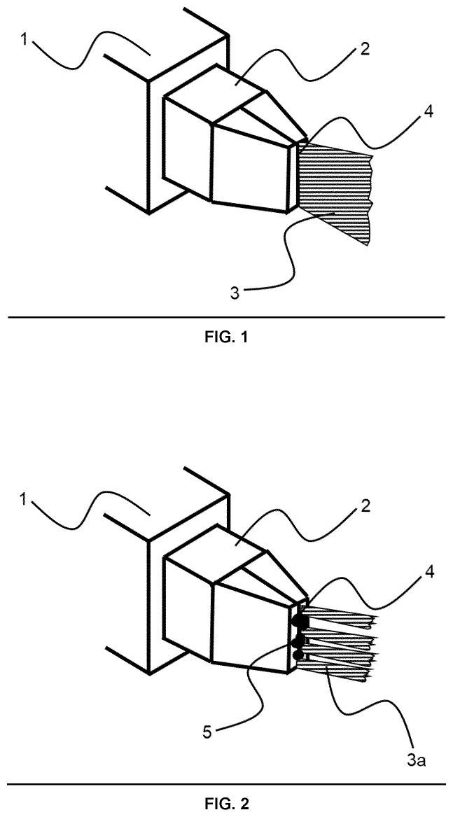

FIG. 1 depicts part of a spray applicator (1) comprising a spray nozzle (2), which is emitting a spray of coating composition (3) from an elongated aperture (4) according to the state of the art.

FIG. 2 indicates that the spray nozzle (2) is partially clogged with coalesced coating composition (5). This results in an uneven spray (3a) of coating composition from an elongated aperture (4). This situation occurs in the prior art.

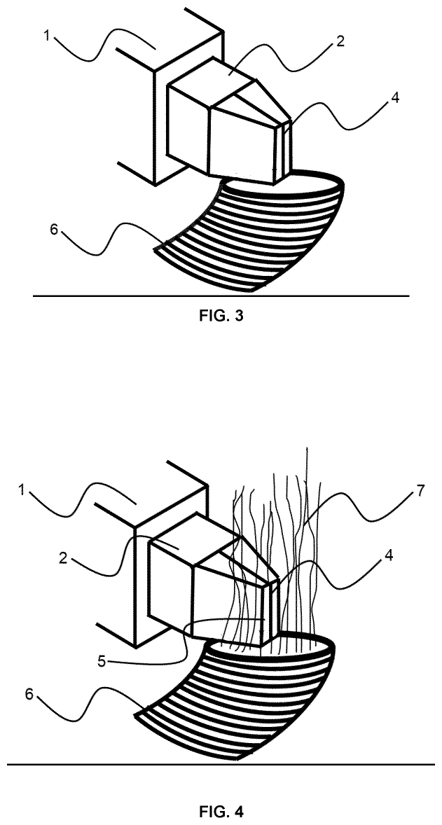

FIG. 3 shows a spray applicator (1) with spray nozzle (2), elongated aperture (4) and a vapor conduit (6) configured to deliver vapor directly onto the exterior of the spray nozzle. The nozzle is not spraying coating composition and no vapor is being emitted; indicating that the equipment is in a standby or off state.

FIG. 4 and FIG. 5 depict embodiments of the spray applicator (1) with spray nozzle (2) and elongated aperture (4) in which a vapor conduit (6) is configured to deliver vapor directly onto the exterior of the spray nozzle (5). FIG. 4 depicts emission of vapor (7) from the vapor conduit and FIG. 5 additionally depicts an even spray of coating composition (3) from the spray nozzle.

FIG. 6 shows the edges of two MDF panels. The top panel edge (8) has been sprayed directly with a waterborne primer using a new and clean spraying nozzle; the bottom panel edge (9) has been sprayed after a 45 minute pause in spraying but with continuous humidification of the spraying nozzle. The curvature of each of the panel edges (8) and (9) into panel sides (10) and (11) is visible. It can be seen that there is no significant visible difference between the edges sprayed with a new, clean nozzle (8) and the edge sprayed after a 45 minute pause in spraying (9).

FIG. 7 shows the edge of an MDF panel (12) sprayed with the same waterborne primer as used in FIG. 6 but after a pause in spraying of 15 minutes and without any humidification of the spraying nozzle. Parts of the edge are coated (13) and parts are uncoated (14). The coated part itself is also uneven. The poor coverage indicates clogging of the spray nozzle with coating composition and poor atomization of the coating composition by the spray nozzle.

### Example

A water-borne primer, Aqua Surf 809 (AkzoNobel), was sprayed onto the edge of a panel of an engineered wood substrate, namely MDF, in a TTEPS edge coater (Trivec) using low pressure spray applicator equipment with an output pressure at the spray nozzle of 0.5 MPa. A 25 mm length slit-aperture Control Coat spray nozzle (Nordson) was used. The coating composition applied was 150 g/m². After the initial spraying application, the paint was left in the apparatus during a pause in spraying of 45 minutes to simulate an unpredictable stop in a spraying production line. During the spraying and the stop in spraying, water vapor generated by ultrasound in an Airwin humidifier (Boga) was continuously fed by hose to the outside of the spray nozzle. No clogging of the nozzle was visible after the pause. A second edge of the panel of MDF was then spray coated, while water vapor was continuously applied. A uniform and smooth surface appearance of the edge of the MDF panel resulted. The two edges coated are shown in FIG. 6; the initial coated edge (8) and coated edge after pausing (9) are both evenly coated.

### Comparative Experiment

The Example was repeated, except that at no point in the process was water vapor generated or supplied to the spray nozzle. During the pause in spraying it was evident that clogging occurred at the nozzle surface, especially in the central part of the nozzle. Spray coating of the second edge of the panel of MDF gave a very uneven surface appearance with two separate lines of coating applied and some parts of the MDF surface not covered at all by paint as shown in FIG. 7.

The Examples illustrate the effectiveness of the apparatus and process of the present disclosure in reducing clogging of a spray nozzle following a pause in spraying.

1. An apparatus for depositing a coating composition onto a substrate, said apparatus comprising:
a) a spray applicator (1) comprising a coating composition reservoir, a pump, a spray nozzle (2) and a coating composition conduit configured to connect the coating composition reservoir to the spray nozzle (2);
b) a vapor emitter; and
c) electromechanical means for automatically moving the spray nozzle (2) relative to the substrate;
the vapor emitter being configured to emit a stream of vapor (7) directly onto the spray nozzle (2), both during spraying and during a pause in spraying, and which vapor emitter comprising:
i) a fluid reservoir capable of holding the fluid to be vaporized;
ii) a vaporizer configured to convert the fluid to a vapor; and
iii) a vapor conduit (6) configured to deliver the stream of vapor (7) from the vaporizer through a vapor conduit (6) aperture directly onto the spray nozzle, the vapor being conveyed through the vapor conduit (6) by a fan connected to the vapor conduit.

2. The apparatus according to claim 1, wherein the vaporizer comprises an ultrasonic transducer.

3. The apparatus according to claim 1, wherein the spray nozzle (2) is configured to move in a plane perpendicular to the relative direction of movement of the substrate to the spray nozzle (2).

4. The apparatus according to claim 1, wherein the vapor conduit (6) aperture is located within 60 mm of the spray nozzle (2).

5. A process for depositing a coating composition on a substrate, said process comprising simultaneously;
a) providing a coating composition to a spray nozzle (2) and spraying the coating composition from the spray nozzle (2) onto the substrate;
b) emitting a stream of vapor (7) from a vapor conduit (6) aperture of a vapor emitter; and
c) moving automatically by electromechanical means the spray nozzle (2) relative to the substrate;
stream of vapor being emitted from the aperture of the vapor emitter directly onto the spray (2), the vapor conduit aperture being located within 100 mm of the spray nozzle (2), the being conveyed through the vapor conduit (6) by a fan connected to the vapor conduit.

6. The process according to claim 5, wherein the coating composition is sprayed intermittently onto one or more substrates and the vapor is emitted continuously directly onto the spray nozzle (2).

7. The process according to claim 5, wherein the coating composition is provided to the spray nozzle (2) at a pressure of from 0.1 to 2 MPa.

8. The process according to claim 5, wherein the vapor provided to the spray nozzle (2) is at a temperature of from 10° C. to 40° C.

9. The process according to claim 5, wherein the vapor is water vapor and the coating composition is a water-based coating composition.

10. The process according to claim 9, wherein the humidity at the spray nozzle (2) is at least 90%.

11. The process according to claim 5, wherein the vapor is generated from a fluid by an ultrasonic transducer in contact with the fluid.

12. The process according to claim 5, wherein the spray nozzle (2) automatically moves in a plane perpendicular to the relative direction of movement of the substrate to the spray nozzle (2).

13. The process according to claim 5, wherein the substrate is solid wood or engineered wood.

14. The process according to claim 5, which process is a continuous process of coating multiple substrates.

15. (canceled)

16. The process of claim 5, wherein the process is carried out using an apparatus comprising:
a) a spray applicator (1) comprising a coating composition reservoir, a pump, a spray nozzle (2) and a coating composition conduit configured to connect the coating composition reservoir to the spray nozzle (2);
b) a vapor emitter; and
c) electromechanical means for automatically moving the spray nozzle (2) relative to the substrate;
the vapor emitter being configured to emit a stream of vapor (7) directly onto the spray nozzle (2), both during spraying and during a pause in spraying, and which vapor emitter comprising:
i) a fluid reservoir capable of holding the fluid to be vaporized;
ii) a vaporizer configured to convert the fluid to a vapor; and
iii) a vapor conduit (6) configured to deliver the stream of vapor (7) from the vaporizer through a vapor conduit (6) aperture directly onto the spray nozzle, the vapor being conveyed through the vapor conduit (6) by a fan connected to the vapor conduit.
